(19) United States
(12) Patent Application Publication
(10) Pub. No.: US 2026/0130016 A1
(43) Pub. Date: May 7, 2026

(54) ELECTRONIC CHIP AND ELECTRONIC DEVICE INCLUDING THE SAME

(71) Applicant: ELECTRONICS AND TELECOMMUNICATIONS RESEARCH INSTITUTE, Daejeon (KR)

(72) Inventors: Ji-Young OH, Daejeon (KR); Jae Bon KOO, Daejeon (KR); Kyung Hyun KIM, Daejeon (KR); Yong Suk YANG, Daejeon (KR); Yongjun LEE, Daejeon (KR); Jae-Eun PI, Daejeon (KR); Chi-Sun HWANG, Daejeon (KR)

(73) Assignee: ELECTRONICS AND TELECOMMUNICATIONS RESEARCH INSTITUTE, Daejeon (KR)

(21) Appl. No.: 19/378,011

(22) Filed: Nov. 3, 2025

(30) Foreign Application Priority Data
Nov. 6, 2024 (KR) 10-2024-0156507
Aug. 6, 2025 (KR) 10-2025-0108168

(51) Int. Cl. H10H 20/84; H10H 20/857

(52) U.S. Cl. CPC H10H 20/84; H10H 20/857

(57) ABSTRACT

Provided is an electronic chip including a substrate, conductive pads disposed on a first surface of the substrate, and a connection layer covering the first surface and the conductive pads, wherein the connection layer includes an adhesive layer, and metal particles dispersed in the adhesive layer, wherein the adhesive layer includes tannic acid and polyalcohol.

### CROSS-REFERENCE TO RELATED APPLICATIONS

This U.S. non-provisional patent application claims priority under 35 U.S.C. § 119 of Korean Patent Application Nos. 10-2024-0156507, filed on Nov. 6, 2024, and 10-2025-0108168, filed on Aug. 6, 2025, the entire contents of which are hereby incorporated by reference.

### BACKGROUND

The present disclosure herein relates to an electronic chip and an electronic device including the same, and more particularly, to an electronic chip including a connection layer, and an electronic device including the electronic chip.

As modern society develops into an advanced information age, the importance of the semiconductor and display industries is increasing. Typically, a process of forming a solder bump on a pad of a substrate patterned with a wire and attaching a semiconductor chip to electrically connect the pad and the solder bump is applied to a transfer bonding process of an electronic device. Recently, as the size of semiconductor chips, LEDs, or the like has decreased to a micro size, studies have continued on the formation of micro-sized solder bumps, a method for transferring microchips, and a bonding process.

### SUMMARY

The present disclosure provides an electronic chip with improved productivity and an electronic device including the same.

The object to be achieved by the inventive concept is not limited to the above-mentioned object, and other objects that are not mentioned may be apparent to those skilled in the art from the following description.

An embodiment of the inventive concept provides an electronic chip including a substrate, conductive pads disposed on a first surface of the substrate, and a connection layer covering the first surface and the conductive pads, wherein the connection layer includes an adhesive layer, and metal particles dispersed in the adhesive layer, wherein the adhesive layer includes tannic acid and polyalcohol.

According to some embodiments, the metal particles may include at least one of gold (Au), silver (Ag), copper (Cu), tin (Sn), titanium (Ti), tungsten (W), molybdenum (Mo), iron (Fe), zinc (Zn), indium tin oxide (ITO), or an alloy thereof.

According to some embodiments, the metal particles may have a spherical shape, a rod shape, or a flake shape.

According to some embodiments, each of the conductive pads may have a width of approximately 100 nm to approximately 500 nm, and adjacent conductive pads may have a distance of approximately 100 nm to approximately 250 nm therebetween.

According to some embodiments, the metal particles may have a particle diameter of approximately 0.1 times to approximately 1 time the width of each of the conductive pads, and approximately 0.1 times to approximately 0.5 times the distance between the conductive pads.

According to some embodiments, the metal particles may be connected to the conductive pads.

According to some embodiments, the metal particles dispersed in the adhesive layer may have an application area of approximately 40% to approximately 70% of the total area of the conductive pads in a plane view.

According to some embodiments, the polyalcohol may include at least one of polyvinyl alcohol, polyethylene glycol, or polypropylene glycol.

According to some embodiments, the connection layer may have a thickness of approximately 1 μm to approximately 10 μm from the first surface of the substrate.

In an embodiment of the inventive concept, an electronic device includes a base substrate, electrodes disposed on the base substrate, and an electronic chip disposed on some corresponding electrodes among the electrodes, wherein the electronic chip includes a substrate, conductive pads disposed on a first surface of the substrate, and a connection layer covering the first surface and the conductive pads, interposed between the substrate and the electrodes, and in contact with the electrodes, wherein the connection layer includes an adhesive layer, and metal particles dispersed in the adhesive layer, wherein the adhesive layer includes polyphenol and polyalcohol.

According to some embodiments, the polyphenol may include at least one of flavonoid, phenolic acid, stilbene, lignan, or tannic acid, and the polyalcohol may include at least one of polyvinyl alcohol, polyethylene glycol, or polypropylene glycol.

According to some embodiments, the metal particles may include at least one of iron (Fe), zinc (Zn), molybdenum (Mo), tungsten (W), or an alloy thereof.

According to some embodiments, the metal particles may have a particle diameter of approximately 10 nm to approximately 250 nm.

According to some embodiments, the connection layer may further include an air gap between the metal particles.

According to some embodiments, the base substrate may include at least one of a glass substrate, a flexible substrate, a stretchable substrate, or a biodegradable substrate.

According to some embodiments, the connection layer may be exposed toward the base substrate between the electrodes and have a surface spaced apart from the base substrate.

According to some embodiments, the connection layer may have a maximum width greater than the width of the substrate, and the connection layer may be extended to cover a portion of a side surface of the substrate.

In an embodiment of the inventive concept, an electronic device includes a base substrate, electrodes disposed on the base substrate, and an electronic chip disposed on some corresponding electrodes among the electrodes, wherein the electronic chip includes a substrate, conductive pads disposed on a first surface of the substrate, and a connection layer covering the first surface and the conductive pads, interposed between the substrate and the electrodes, and in contact with the electrodes, wherein the connection layer includes an adhesive layer, metal particles dispersed in the adhesive layer, and an air gap between the metal particles, wherein the adhesive layer includes tannic acid.

According to some embodiments, the adhesive layer may include at least one of polyvinyl alcohol, polyethylene glycol, or polypropylene glycol.

According to some embodiments, the conductive pads may be connected to the electrodes through the metal particles.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of an electronic chip according to embodiments of the inventive concept;

FIG. 2 is a schematic plan view of an electronic device according to embodiments of the inventive concept;

FIG. 3 is a cross-sectional view taken along line A-A′ of FIG. 2 according to embodiments of the inventive concept;

FIGS. 4A and 4B are enlarged views of portion ‘R1’ of FIG. 2;

FIG. 5A and FIG. 5B are enlarged views of portion ‘R2’ of FIG. 4;

FIG. 6 and FIG. 7 are flowcharts showing a method for manufacturing an electronic device according to embodiments of the inventive concept;

FIG. 8A to FIG. 8H are cross-sectional views sequentially showing a process of manufacturing an electronic device having a cross-section of FIG. 4 according to embodiments of the inventive concept;

FIG. 9A and FIG. 9B are enlarged views of portion ‘R3’ of FIG. 8F;

FIG. 10A is an enlarged view of portion ‘R4’ of FIG. 8G;

FIG. 10B is an enlarged view of portion ‘R5’ of FIG. 8H;

FIG. 11A and FIG. 11B are cross-sectional views showing a process of manufacturing an electronic device according to embodiments of the inventive concept;

FIG. 12 is a flowchart showing a method for manufacturing an electronic device according to embodiments of the inventive concept;

FIG. 13A and FIG. 13B are cross-sectional views sequentially showing a process of manufacturing an electronic chip according to embodiments of the inventive concept;

FIG. 14 shows microscope images of an electronic chip according to embodiments of the inventive concept;

FIG. 15 shows photographs of an experiment of bonding an electronic chip on a substrate according to embodiments of the inventive concept, and then confirming light emission characteristics; and

FIG. 16 shows photographs of an experiment of bonding an electronic chip on a substrate according to embodiments of the inventive concept, and then performing a tensile test.

### DETAILED DESCRIPTION

In order to facilitate sufficient understanding of the configuration and effects of the inventive concept, preferred embodiments of the inventive concept will be described with reference to the accompanying drawings. However, the inventive concept is not limited to the embodiments set forth below, and may be embodied in various forms and modified in many alternate forms. Rather, these embodiments are provided such that the disclosure of the inventive concept will be thorough and complete, and will fully convey the scope of the inventive concept to those skilled in the art to which the inventive concept pertains.

In the present disclosure, when an element is referred to as being on another element, it means that the element may be directly formed on another element, or that a third element may be interposed therebetween. Also, in the drawings, the thickness of elements are exaggerated for an effective description of technical contents. Like reference numerals refer to like elements throughout the specification.

Embodiments described in the present specification will be described with reference to cross-sectional views and/or plan views which are ideal illustrations of the inventive concept. In the drawings, the thickness of films and regions are exaggerated for an effective description of technical contents. Thus, the regions illustrated in the drawings have schematic properties, and the shapes of the regions illustrated in the drawings are intended to exemplify specific shapes of regions of a device and are not intended to limit the scope of the inventive concept. Although the terms first, second, third, and the like are used in various embodiments of the inventive concept to describe various components, these components should not be limited by these terms. These terms are only used to distinguish one element from another. The embodiments described and exemplified herein also include the complementary embodiments thereof.

The terms used herein are for the purpose of describing embodiments and are not intended to be limiting of the inventive concept. In the present specification, singular forms include plural forms unless the context clearly indicates otherwise. As used herein, the terms ‘comprises’ and/or ‘comprising’ are intended to be inclusive of the stated elements, and do not exclude the possibility of the presence or the addition of one or more other elements.

In the present specification, unless otherwise defined, a particle diameter may be an average particle diameter. In addition, the particle diameter refers to an average particle diameter (D₅₀) meaning a diameter of a particle having a cumulative volume of 50 vol % in a particle size distribution. The average particle diameter (D₅₀) may be measured by a method widely known to those skilled in the art, and may be measured, for example, using a particle size analyzer, or using a transmission electron microscope (TEM) photograph or scanning electron microscope (SEM) photograph. As another method, a measurement device using dynamic light-scattering may be used to perform measurement, the number of particles for each particle size range may be counted by performing data analysis, and then an average particle diameter (D₅₀) value may be obtained by performing calculated therefrom. Alternatively, the average particle diameter (D₅₀) may be measured by a laser diffraction method.

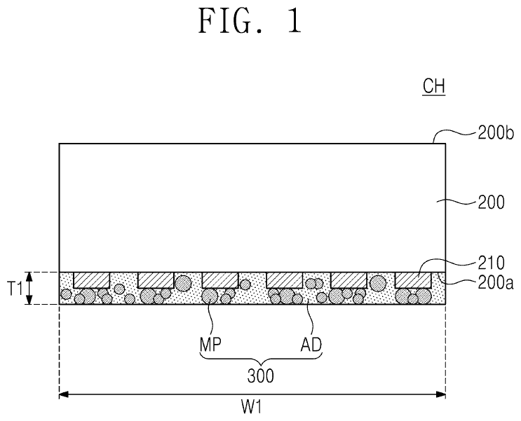

FIG. 1 is a cross-sectional view of an electronic chip according to embodiments of the inventive concept.

Referring to FIG. 1, an electronic chip CH according to the present embodiments may include a substrate 200, conductive pads 210, and a connection layer 300. The electronic chip CH may be, for example, a semiconductor chip, an LED micro device, or the like. The electronic chip CH may have, for example, a first width W1 of approximately 1 μm to approximately 500 μm.

The substrate 200 may include, for example, silicon, sapphire, gallium, or germanium. A transistor and a wire may be disposed on a substrate 200. Although not illustrated, the electronic chip CH may include an active layer or an insulation layer.

The conductive pads 210 may be disposed on a first surface 200a of the substrate 200. The conductive pads 210 may be spaced apart from each other. The conductive pads 210 may include, for example, at least one metal among copper (Cu), gold (Au), nickel (Ni), tin (Sn), silver (Ag), tungsten (W), or aluminum (Al).

The connection layer 300 may be disposed on the first surface 200a of the substrate 200. The connection layer 300 may cover the first surface 200a of the substrate 200, and the conductive pads 210. The connection layer 300 may have a first thickness T1 of approximately 1 μm to approximately 10 μm from the first surface 200a of the substrate 200. The connection layer 300 may include an adhesive layer AD and metal particles MP. The metal particles MP may be distributed within the adhesive layer AD. The metal particles MP may be connected to the conductive pads 210.

The adhesive layer AD may include a hydrogel material. The adhesive layer AD may include, for example, a polyphenol such as flavonoid, phenolic acid, stilbene, lignan, or tannic acid. More preferably, the adhesive layer AD may include tannic acid. In addition, the adhesive layer AD may include, for example, a polyalcohol such as polyvinyl alcohol, polyethylene glycol, or polypropylene glycol. The adhesive layer AD has flexible properties, which may make it strong against an external impact, and easy to bond the electronic chip CH onto a stretchable substrate.

The metal particles MP may have, for example, various shapes such as a spherical shape, a rod shape, or a flake shape. The metal particles MP may include, for example, at least one of gold (Au), silver (Ag), copper (Cu), tin (Sn), titanium (Ti), tungsten (W), molybdenum (Mo), iron (Fe), zinc (Zn), indium tin oxide (ITO), or an alloy thereof. More preferably, the metal particles MP may include gold (Au) not oxidized. As an example, if the metal particles MP include a biodegradable material such as iron (Fe), zinc (Zn), molybdenum (Mo), or tungsten (W), the electronic chip CH may be biodegradable.

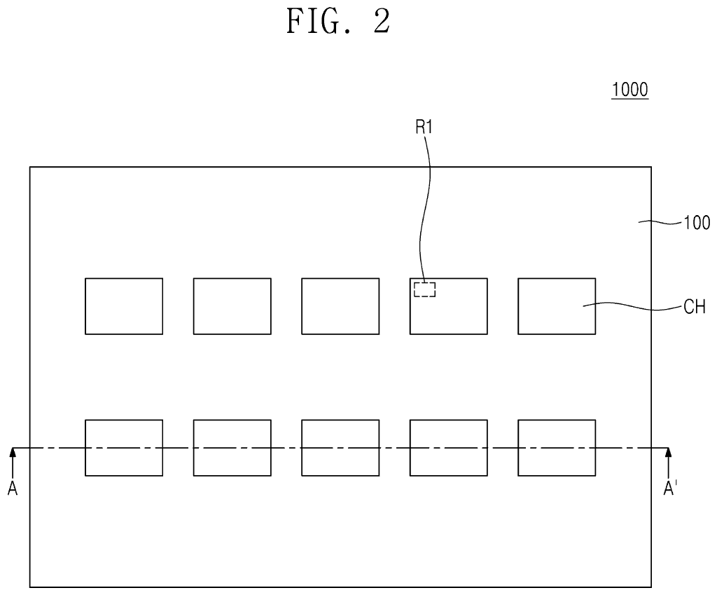

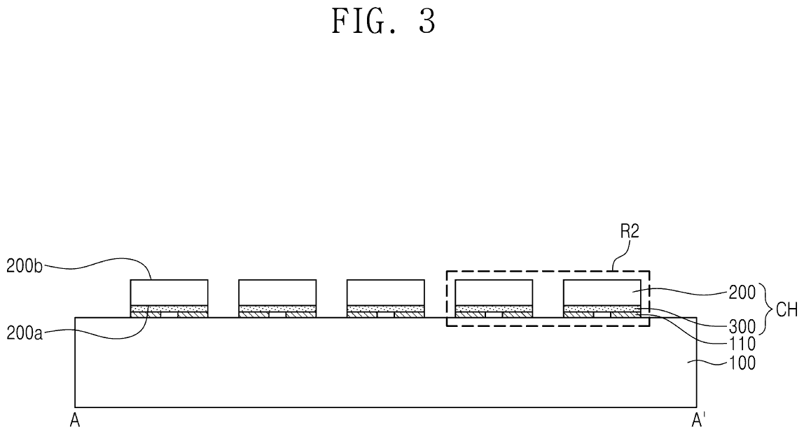

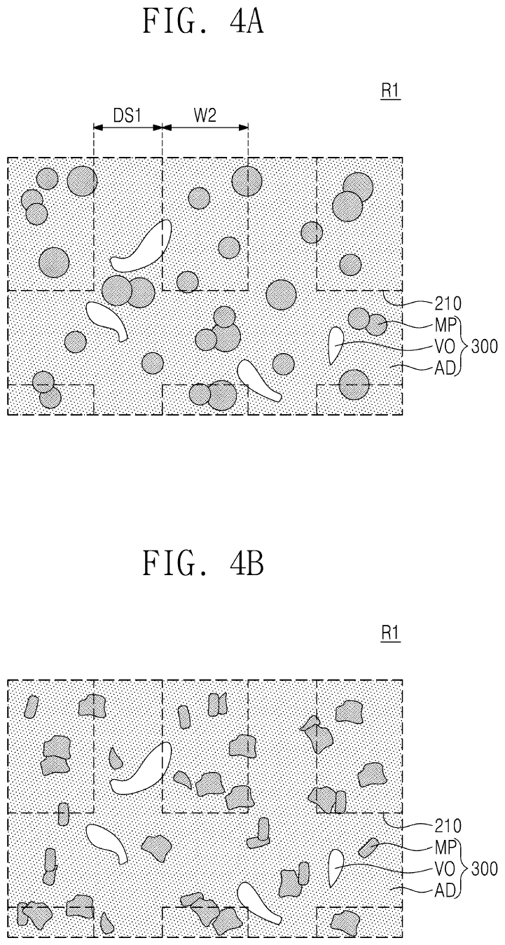

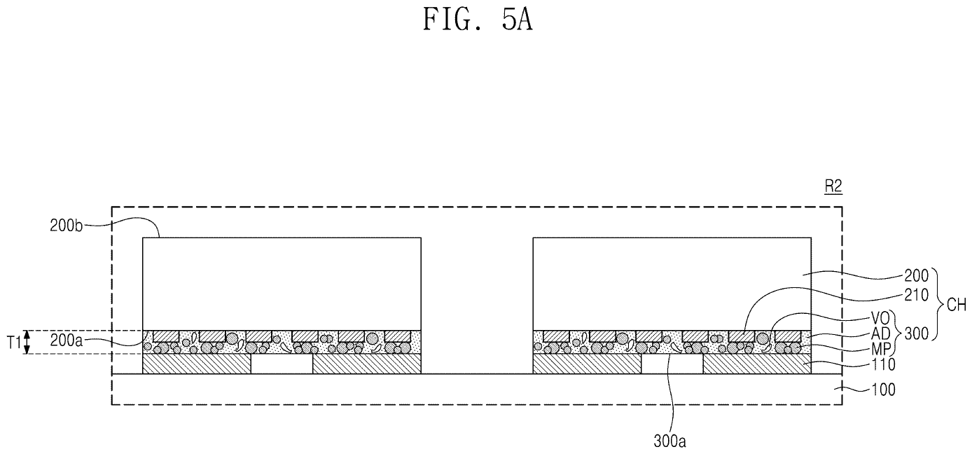

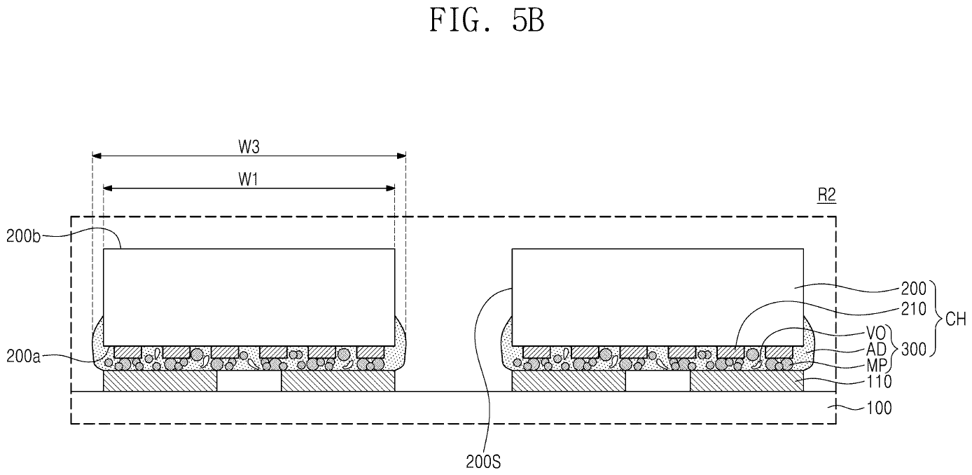

FIG. 2 is a schematic plan view of an electronic device according to embodiments of the inventive concept. FIG. 3 is a cross-sectional view taken along line A-A′ of FIG. 2 according to embodiments of the inventive concept. FIGS. 4A and 4B are enlarged views of portion ‘R1’ of FIG. 2. FIG. 5A and FIG. 5B are enlarged views of portion ‘R2’ of FIG. 3.

Referring to FIG. 2 and FIG. 3, an electronic device 1000 according to the present embodiments may include a base substrate 100 and a plurality of electronic chips CH. The electronic chips CH may be disposed on the base substrate 100 while being spaced apart from each other. Each of the electronic chips CH may be the electronic chip CH described with reference to FIG. 1.

A substrate 10 may be, for example, a silicon single crystal substrate, a silicon on insulator (SOI) substrate, a germanium substrate, and/or a silicon-germanium substrate. Alternatively, the base substrate 100 may include a transparent material, and may include, for example, at least one of a glass single layer or a transparent plastic film. That is, the base substrate 100 may be a glass substrate or a plastic substrate. Alternatively, the base substrate 100 may be, for example, a flexible substrate, a stretchable substrate, or a biodegradable substrate.

Electrodes 110 may be disposed spaced apart from each other on the base substrate 100. The electronic chips CH respectively corresponding to the electrodes 110 may be disposed on the electrodes 110. That is, the electrodes 110 may be electrically connected to the corresponding electronic chips CH, respectively. The electrodes 110 may include a single film or a multi-layered film. The electrodes 110 may include a transparent conductive material. The electrodes 110 may include, for example, a mixed material form containing at least one of indium tin oxide (ITO), indium zinc oxide (IZO), silver nanowire, aluminum, carbon nanotube (CNT), graphene, PEDOT:Pss, polyaniline, or polythiophene. Alternatively, the electrodes 110 may include, for example, a metal such as gold (Au), silver (Ag), copper (Cu), aluminum (Al), tungsten (W), molybdenum (Mo), cobalt (Co), or manganese (Mg). Alternatively, the electrodes 110 may include rubidium (Ru), platinum (Pt), or polysilicon.

Referring to FIG. 2 and FIG. 4A, metal particles MP according to an embodiment may have a spherical shape. Each of conductive pads 210 may have a second width W2 of approximately 100 nm to approximately 500 nm. Adjacent conductive pads 210 may have a first distance DS1 of approximately 100 nm to approximately 250 nm. The metal particles MP may have a particle diameter of approximately 0.1 times to 1 time the second width W2. The metal particles MP may have a particle diameter of approximately 0.1 times to 0.5 times the first distance DS1. For example, the metal particles MP may have a particle diameter of approximately 10 nm to approximately 250 nm. In a plan view, the metal particles MP may be uniformly distributed and positioned on a first surface 200a of a substrate 200, and the conductive pads 210. The metal particles MP dispersed on the first surface 200a and the conductive pads 210 (i.e., dispersed in an adhesive layer AD) may have an application area of approximately 40% to approximately 70% of the total area of the conductive pads 210 in a plan view.

Referring to FIG. 4B, the metal particles MP according to an embodiment may have a shape such as a rod shape or a flake shape. In this case, the metal particles MP have an increased contact area, which may facilitate bonding between the metal particles MP and the adhesive layer AD, and may facilitate electrical connection between the electronic chip CH and the electrodes 110 through the metal particles MP.

In the electronic device 1000, the electronic chip CH mounted on the base substrate 100 may include an air gap VO in a connection layer 300. The air gap VO may be positioned between the metal particles MP. The size and shape of the air gap VO may vary.

Referring to FIG. 5A, the metal particles MP of the connection layer 300 may be connected to the conductive pads 210 and the electrodes 110. The conductive pads 210 may be electrically connected to the electrodes 110 through the metal particles MP. The connection layer 300 may include a surface 300a exposed toward the base substrate 100 between the electrodes 110. That is, the connection layer 300 may be spaced apart from the base substrate 100 between the electrodes 110.

Referring to FIG. 5B, the adhesive layer AD according to an embodiment may extend to cover a portion of a side surface 200S of the substrate 200. The connection layer 300 may have a maximum width, that is, a third width W3, which is greater than the first width W1 of the electronic chip CH.

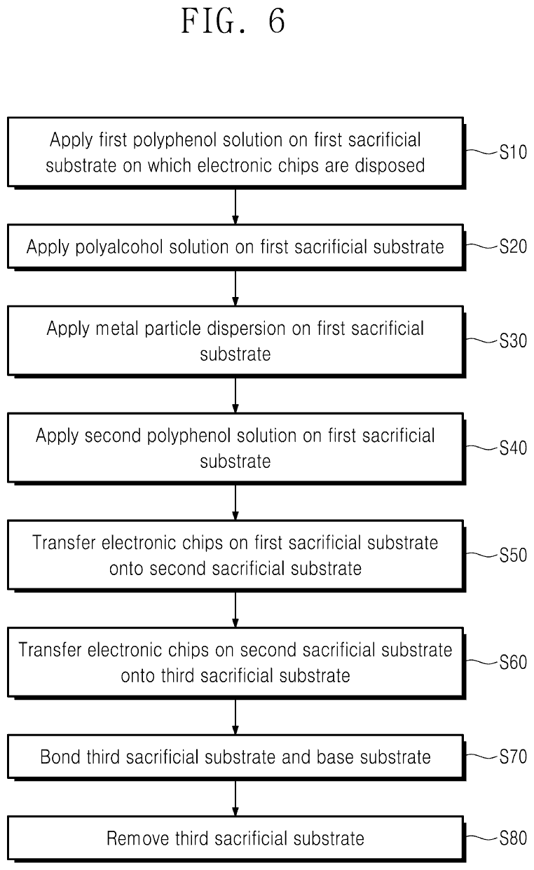

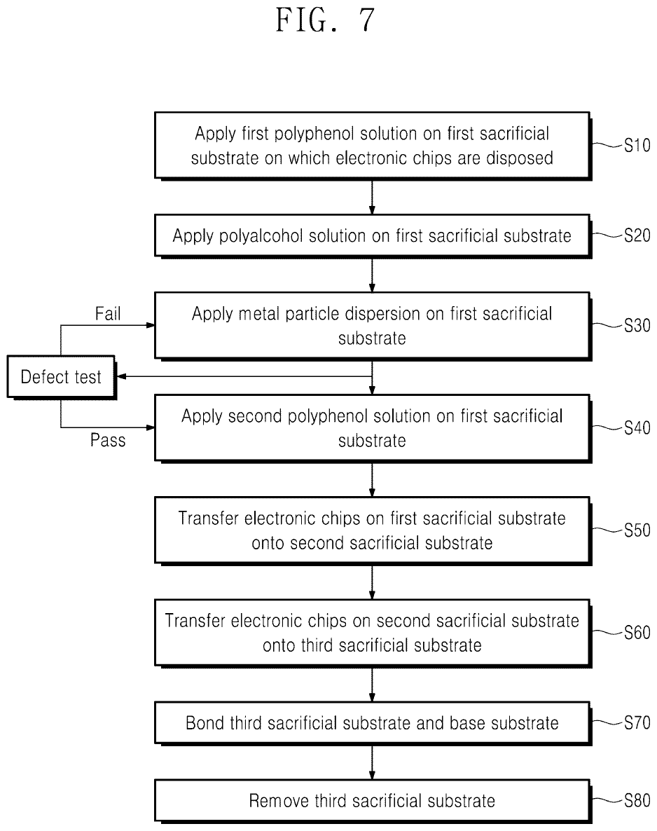

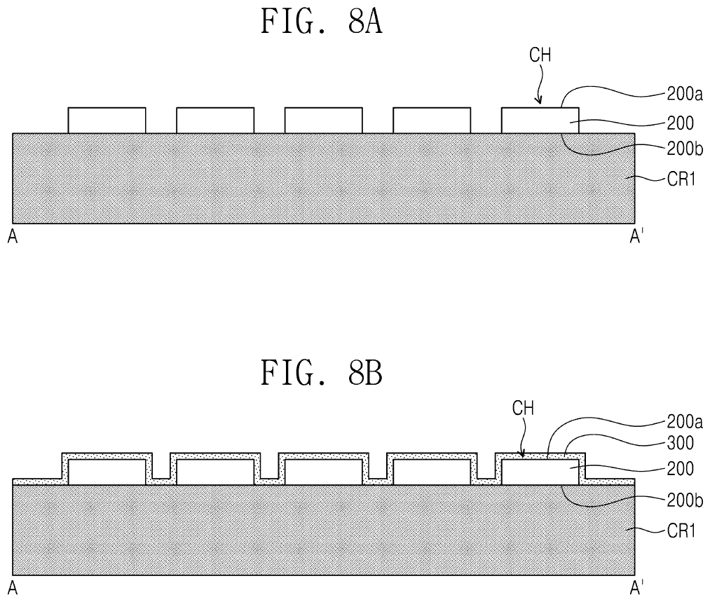

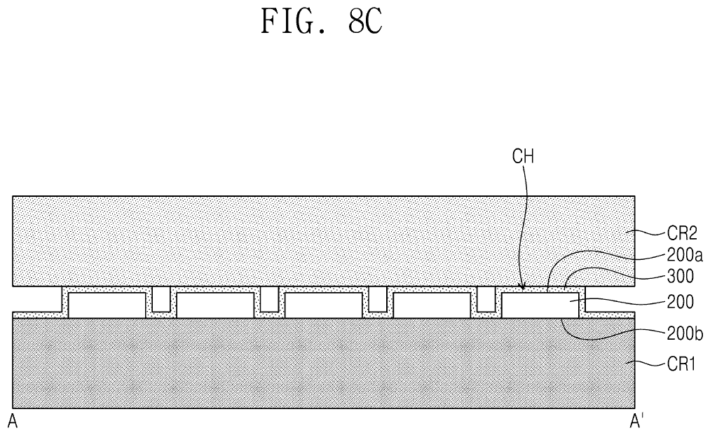

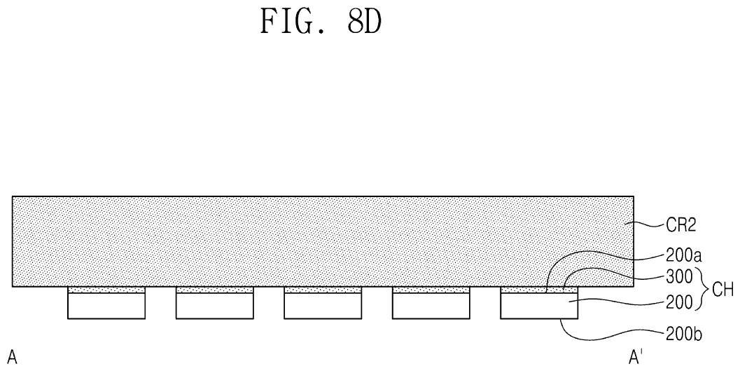

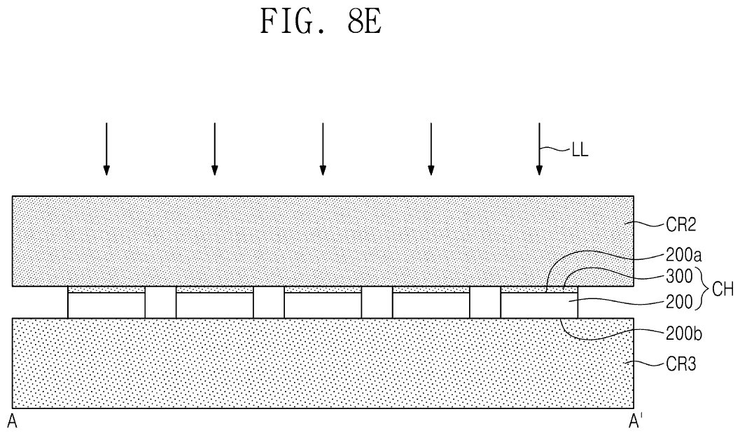

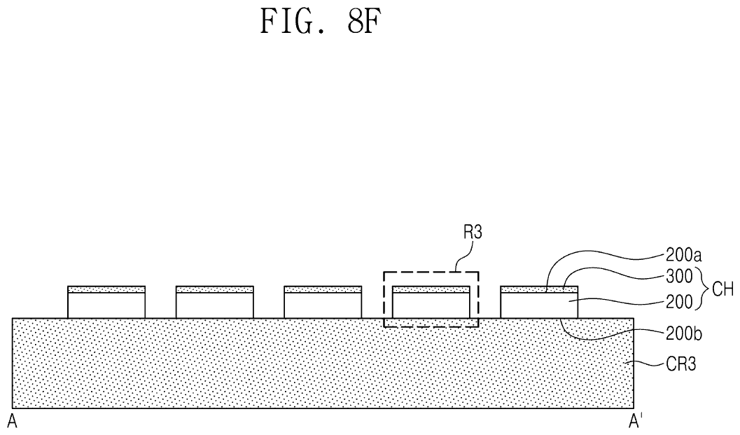

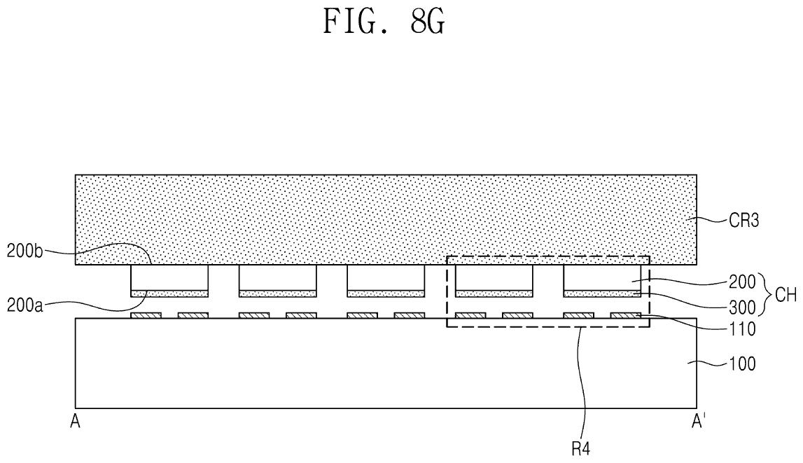

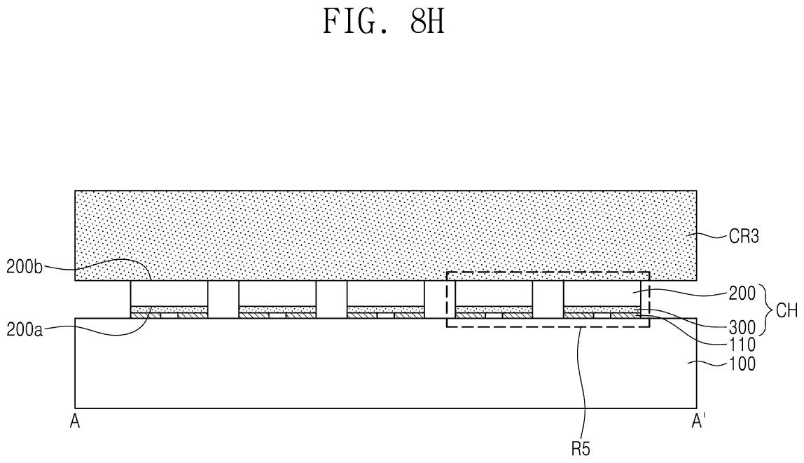

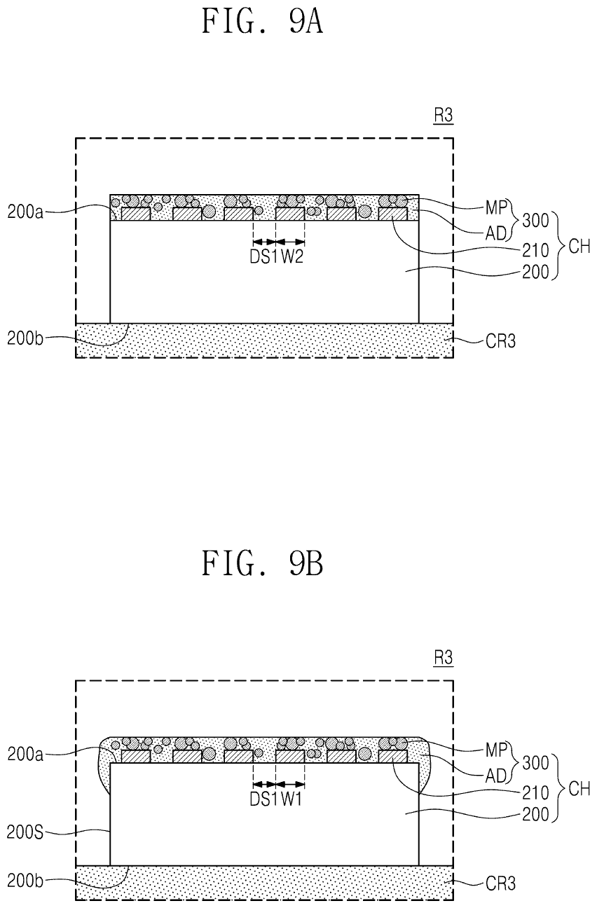

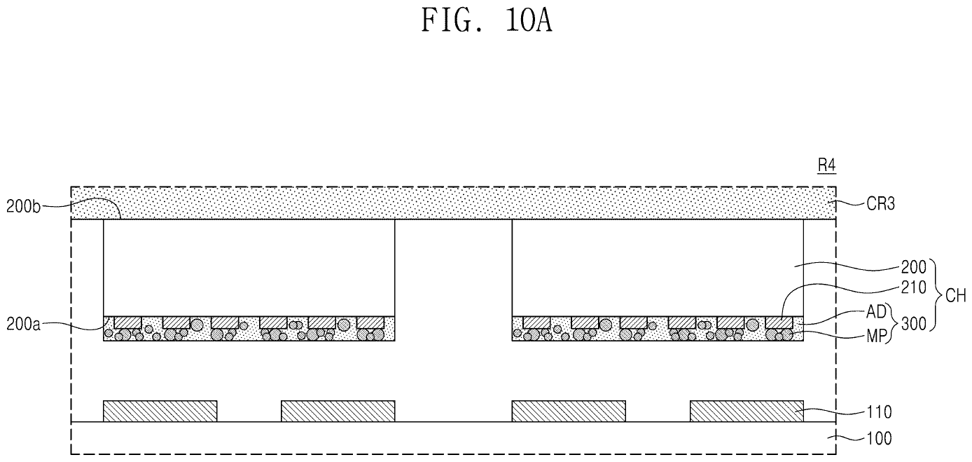

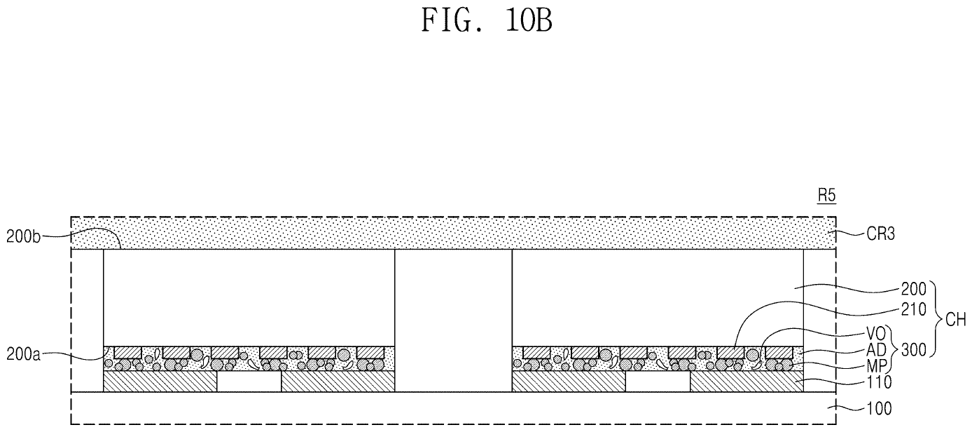

FIG. 6 and FIG. 7 are flowcharts showing a method for manufacturing an electronic device according to embodiments of the inventive concept. FIG. 8A to FIG. 8H are cross-sectional views sequentially showing a process of manufacturing an electronic device having a cross-section of FIG. 4 according to embodiments of the inventive concept. FIG. 9A and FIG. 9B are enlarged views of portion ‘R3’ of FIG. 8F. FIG. 10A is an enlarged view of portion ‘R4’ of FIG. 8G. FIG. 10B is an enlarged view of portion ‘R5’ of FIG. 8H.

Referring to FIG. 6 and FIG. 8A, a first sacrificial substrate CR1 on which a plurality of electronic chips CH are disposed may be prepared. Each of the electronic chips CH may include a substrate 200. The substrate 200 may include a first surface 200a and a second surface 200b, which are opposite to each other. The electronic chips CH may be positioned such that the second surface 200b of the substrate 200 faces the first sacrificial substrate CR1. Although not illustrated, conductive pads 210 (see FIG. 1) may be disposed on the first surface 200a of the substrate 200. The first sacrificial substrate CR1 may be a carrier substrate or a silicon polymer (e.g., polydimethylsiloxane (PDMS)) substrate.

Referring to FIG. 6 and FIG. 8B, a connection layer 300 covering the first sacrificial substrate CR1 and the electronic chips CH may be formed. A step of forming the connection layer 300 may include steps (S10, S20, S30, and S40) of applying a first polyphenol solution, a second polyphenol solution, a polyalcohol solution, and a metal particle dispersion onto the first sacrificial substrate CR1. A detailed process of forming the connection layer 300 is as follows.

First, the first polyphenol solution may be applied on the first sacrificial substrate CR1 (S10). The first polyphenol solution may be, for example, a tannic acid aqueous solution of approximately 10 wt % or less. The first polyphenol solution may cover the first sacrificial substrate CR1 and the electronic chips CH. Next, the polyalcohol solution may be applied on the first sacrificial substrate CR1 on which the first polyphenol solution is applied (S20). The polyalcohol solution may be, for example, a polyvinyl alcohol aqueous solution of approximately 10 wt % or less. The polyalcohol solution may cover the first sacrificial substrate CR1 and the electronic chips CH. Next, the metal particle dispersion may be applied on the first sacrificial substrate CR1 on which the polyalcohol solution is applied (S30). The metal particle dispersion may include the metal particles MP described with reference to FIG. 1 to FIG. 5B. The concentration or application amount of the metal particle dispersion may be adjusted to adjust the content of the metal particles MP in the connection layer 300. The metal particle dispersion may include water or an organic solvent, and a binder. The metal particle dispersion may cover the first sacrificial substrate CR1 and the electronic chips CH. Next, the second polyphenol solution may be applied on the first sacrificial substrate CR1 on which the metal particle dispersion is applied (S40). The second polyphenol solution may be, for example, a tannic acid aqueous solution approximately 10 wt % or less. The second polyphenol solution may cover the first sacrificial substrate CR1 and the electronic chips CH.

The steps (S10, S20, S30, and S40) of applying the first polyphenol solution, the second polyphenol solution, the polyalcohol solution, and the metal particle dispersion may each be performed, for example, by a spray application (spray coating or spray deposition) method. The steps (S10, S20, S30, and S40) of applying the first polyphenol solution, the second polyphenol solution, the polyalcohol solution, and the metal particle dispersion may each include a process of performing the application while heating the first sacrificial substrate CR1, or performing the application, and then heating the first sacrificial substrate CR1 to dry moisture. After the connection layer 300 is formed, the first sacrificial substrate CR1 may be heated to dry moisture in the connection layer 300.

The first polyphenol solution, the second polyphenol solution, and the polyalcohol solution may form an adhesive layer AD (see FIG. 1). The metal particles MP (see FIG. 1) may be dispersed in the adhesive layer AD. After the metal particle dispersion is applied, metal particles applied on the electronic chips CH may have an application area of approximately 40% to approximately 70% of the area of the conductive pads 210 of the electronic chips CH in a plan view. As the application area decreases, the adhesion between the metal particles and the adhesive layer AD may increase, and as the application area increases, the adhesion between the metal particles and the adhesive layer AD may decrease. Thus, the connection layer 300 may be formed, and the connection layer 300 may be the connection layer 300 described with reference to FIG. 1. The connection layer 300 may have anisotropy.

Referring to FIG. 6 and FIG. 8C, a second sacrificial substrate CR2 may be prepared. The second sacrificial substrate CR2 may be positioned on the first sacrificial substrate CR1. That is, the second sacrificial substrate CR2 may be positioned on the first surface 200a of the substrate 200. The second sacrificial substrate CR2 may be attached to the connection layer 300. The second sacrificial substrate CR2 may include a photosensitive material. The second sacrificial substrate CR2 may include, for example, a photosensitive polyimide. Alternatively, the second sacrificial substrate CR2 may include a thermal release material. In this case, the second sacrificial substrate CR2 may include, for example, acryl, urethane, silicon, ceramic, thermoplastic resin, or the like.

Referring to FIG. 6 and FIG. 8D, the electronic chips CH may be transferred onto a second sacrificial substrate CR2 (S50). The adhesion between the second sacrificial substrate CR2 and the connection layer 300 may be greater than the adhesion between the first sacrificial substrate CR1 and the connection layer 300. Therefore, when the first sacrificial substrate CR1 is removed from the electronic chips CH, the electronic chips CH remains attached to the second sacrificial substrate CR2. As the first sacrificial substrate CR1 is removed, a portion of the connection layer 300 not attached to the second sacrificial substrate CR2 may be removed together. Therefore, the connection layer 300 may remain only between the second sacrificial substrate CR2 and the substrate 200. Thus, the electronic chips CH of FIG. 1 including the connection layer 300 may be formed on the second sacrificial substrate CR2.

A portion of the connection layer 300 may also remain on the first sacrificial substrate CR1 removed from the electronic chips CH. The metal particles dispersed in the connection layer 300 on the first sacrificial substrate CR1 may be recovered and reused. The connection layer 300 includes a hydrogel material, and thus, is biodegradable, so that the used connection layer 300 may be dissolved in water to reuse the metal particles. Thus, the manufacturing cost of the electronic device may be reduced.

Referring to FIG. 6, FIG. 8E, and FIG. 8F, a third sacrificial substrate CR3 may be prepared. The third sacrificial substrate CR3 may be a carrier substrate or a silicon polymer (e.g., polydimethylsiloxane (PDMS)) substrate. The second sacrificial substrate CR2 may be positioned on the third sacrificial substrate CR3. The second surface 200b of the substrate 200 may be positioned to face the third sacrificial substrate CR3. For example, if the second sacrificial substrate CR2 includes a photosensitive material, the electronic chips CH on the second sacrificial substrate CR2 may be transferred onto the third sacrificial substrate CR3 though an exposure process (S60). The exposure process may be performed by irradiating light LL. The second sacrificial substrate CR2 may be removed from the electronic chips CH.

Referring to FIG. 8F and FIG. 9A, each of the conductive pads 210 may have a second width W2 of approximately 100 nm to approximately 500 nm. Adjacent conductive pads 210 may have a first distance DS1 of approximately 100 nm to approximately 250 nm. The metal particles MP may have a particle diameter of approximately 0.1 times to 1 time the second width W2. The metal particles MP may have a particle diameter of approximately 0.1 times to 0.5 times the first distance DS1. For example, the metal particles MP may have a particle diameter of approximately 10 nm to approximately 250 nm.

Referring to FIG. 8F and FIG. 9B, in an embodiment, the connection layer 300 may extend to cover a portion of a side surface 200S of the substrate 200.

Referring back to FIG. 6, FIG. 8G, and FIG. 10, a base substrate 100 in which electrodes 110 are disposed on an upper surface thereof may be prepared. The structure of FIG. 8F may be turned over and positioned on the base substrate 100. That is, the first surface 200a of the substrate 200 may be positioned to face the base substrate 100. More specifically, after moisture is sprayed (water application) on the connection layers 300 of the electronic chips CH, the electronic chips CH may be positioned on corresponding electrodes 110, respectively.

Referring to FIG. 6, FIG. 8H, and FIG. 10B, the third sacrificial substrate CR3 and the base substrate 100 may be bonded (S70). For example, the electronic chips CH on the third sacrificial substrate CR3 and the electrodes 110 on the base substrate 100 may be bonded to each other. After the connection layers 300 and the electrodes 110 are brought into close contact with each other, heating may be performed through a heat-treatment process to dry the moisture, thereby bonding the connection layers 300 and the electrodes 110. The heat-treatment process may be performed, for example, at 100° C. for 1 minute to 10 minutes. The connection layer 300 may be cured through the heat-treatment process.

The electronic chips CH and the base substrate 100 may be electrically connected through the metal particles MP dispersed in the connection layer 300. That is, the metal particles MP may connect the conductive pads 210 of the electronic chips CH and the electrodes 110 of the base substrate 100. In this case, by forming only the flow of a current in a vertical direction, it is possible to effectively connect the electronic chips CH having an array of fine patterns to the base substrate 100. In the process of spraying and drying moisture, polyphenol and polyvinyl groups of the adhesive layer AD may be subjected to diffusion (entanglement) and hydrogen bonding. Thus, strong adhesion is formed, so that the electronic chip CH and the electrodes 110 may be physically connected. In addition, polymers of the adhesive layer AD surrounding the metal particles MP may be aggregated to form an air gap VO between the metal particles MP and the adhesive layer AD. Thereafter, the third sacrificial substrate CR3 may be removed (S80), and an additional heat-treatment process may be performed for drying. Thus, an electronic device 1000 having a cross-section of FIG. 3 may be formed.

A process of directly forming a bump or a solder ball on the base substrate 100 is not performed on the electronic device according to the inventive concept. Therefore, it is possible to mass produce the electronic chips CH including the connection layer 300, which makes it possible to decrease process time and costs and increase productivity. In addition, it is possible to form the connection layer 300 on the electronic chip Ch regardless of the size of the electronic chips CH, a wiring pattern, or a gap between the conductive pads 210. Therefore, even if the gap between the connection pads 210 has a fine pitch, the electronic chip CH may be effectively bonded to the base substrate 100.

Referring to FIG. 7 and FIG. 8B, after the metal particle dispersion is applied on the first sacrificial substrate CR1 on which the polyalcohol solution is applied (S30), a defect inspection may be performed. In the defect inspection, the electronic chips CH may be selected by confirming the degree of distribution of the metal particles applied on the electronic chips CH.

If no defects are found in the defect inspection, the second polyphenol solution may be applied directly on the first sacrificial substrate CR1 (S40). However, for example, if the metal particles applied on the electronic chips CH have an application area of less than approximately 40% of the area of the conductive pads 210 of the electronic chips CH in a plan view, or if the metal particles are not evenly applied on the conductive pads 210, the metal particle dispersion may be applied once more on the first sacrificial substrate CR1. Thereafter, the second polyphenol solution may be applied on the first sacrificial substrate CR1 (S40). The defect inspection may be performed once, but is not limited thereto and may be performed several times. Thus, it is possible to reduce defects of the electronic chips CH and minimize a repair process.

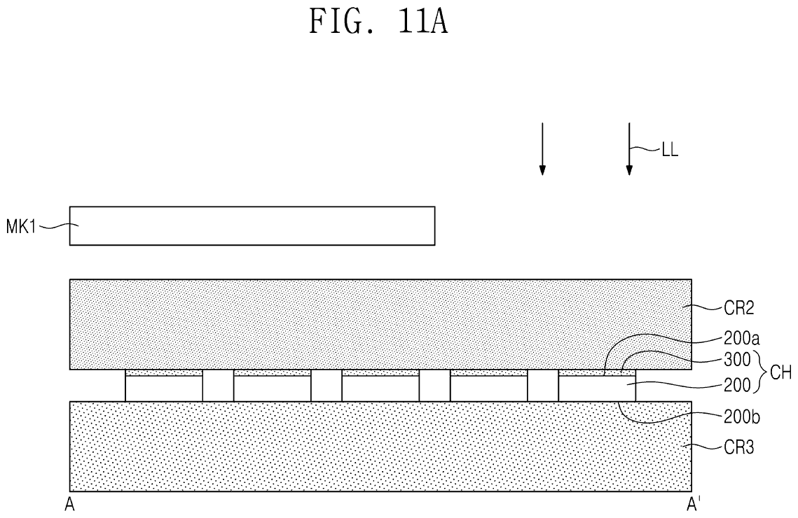

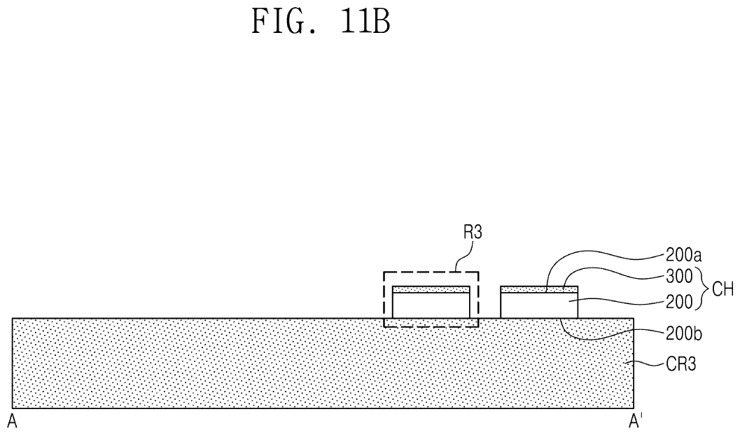

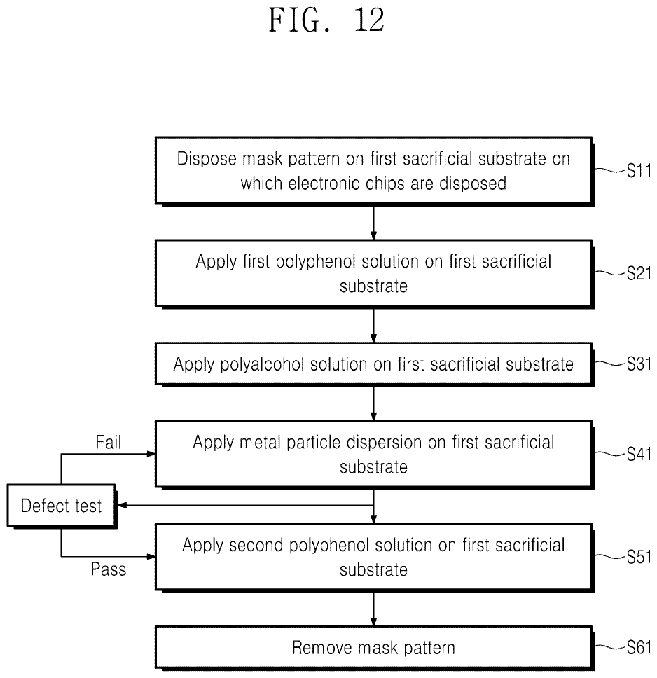

FIG. 11A and FIG. 11B are cross-sectional views showing a process of manufacturing an electronic device according to embodiments of the inventive concept. Hereinafter, redundant descriptions will be omitted.

Referring to FIG. 8E, FIG. 11A, and FIG. 11B, if the second sacrificial substrate CR2 includes a photosensitive material, the electronic chips CH may be selectively transferred onto the third sacrificial substrate CR3. By using a first mask pattern MK1, the second sacrificial substrate CR2 exposed by the first mask pattern MK1 is irradiated with the light LL, so that some of the electronic chips CH may be selectively transferred onto the third sacrificial substrate CR3. An enlarged view of portion ‘R3’ may be the same as/similar to that of FIG. 9A or FIG. 9B.

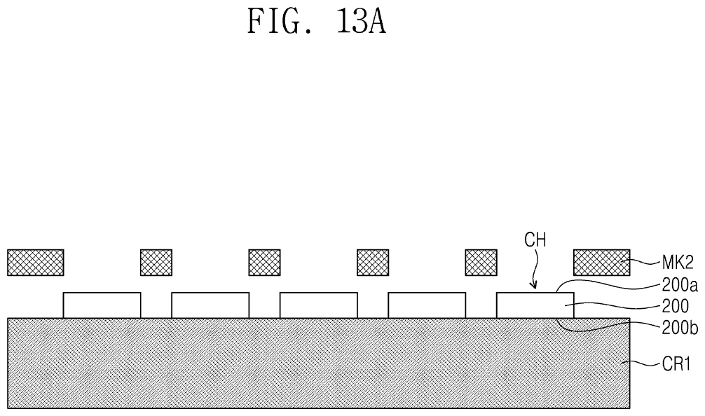

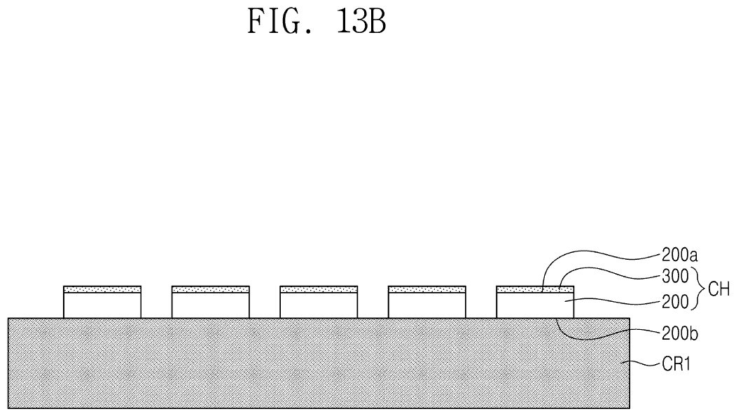

FIG. 12 is a flowchart showing a method for manufacturing an electronic device according to embodiments of the inventive concept. FIG. 13A and FIG. 13B are cross-sectional views sequentially showing a process of manufacturing an electronic chip according to embodiments of the inventive concept.

Referring to FIG. 3, FIGS. 12 and 13A, and FIG. 13B, a second mask pattern MK2 may be disposed on a first sacrificial substrate CR1 on which a plurality of electronic chips CH are disposed (S11). The second mask pattern MK2 may expose the electronic chips CH and cover the first sacrificial substrate CR1. The second mask pattern MK2 may be, for example, a shadow mask.

A connection layer 300 may be formed on each of the electronic chips CH by using the second mask pattern MK2. A step of forming the connection layer 300 may include steps (S21, S31, S41, and S51) of applying a first polyphenol solution, a polyalcohol solution, a metal particle dispersion, and a second polyphenol solution, onto the first sacrificial substrate CR1. A detailed process of forming the connection layer 300 is as described above. In this case, due to the mask pattern MK2, the connection layer 300 may be formed only on each of the electronic chips CH. Thereafter, the second mask pattern MK2 may be removed (S61).

Thereafter, the first sacrificial substrate CR1 and a base substrate 100 may be bonded and the first sacrificial substrate CR1 may be removed to form the electronic device 1000 of FIG. 3. This is as described above. Alternatively, desired ones of the electronic chips CH on the first sacrificial substrate CR1 may be selectively bonded onto the base substrate 100 in a pick-and-place manner to form the electronic device 1000 of FIG. 3.

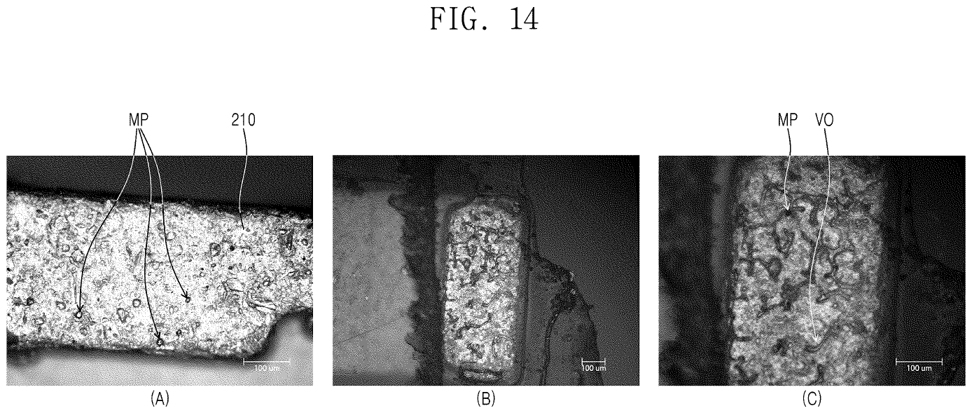

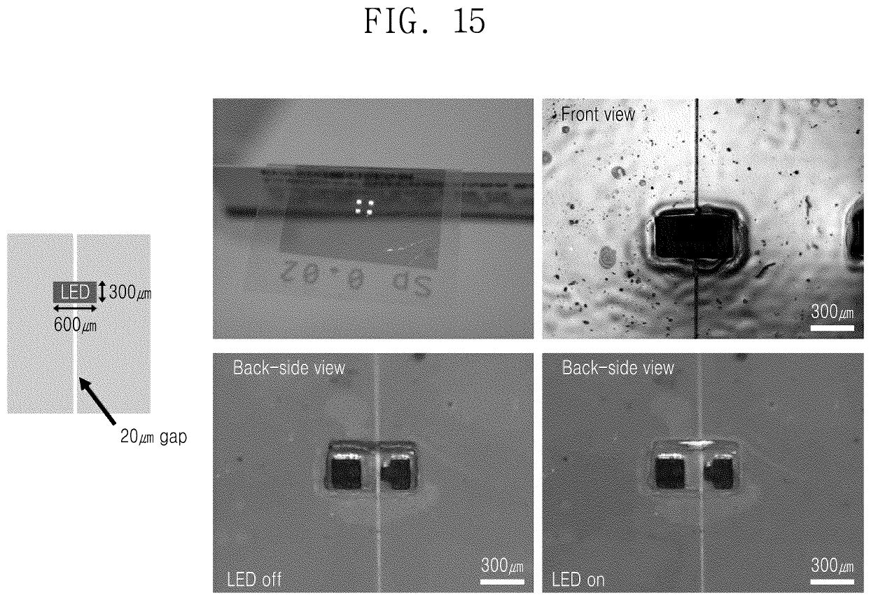

FIG. 14 shows microscope images of an electronic chip according to embodiments of the inventive concept.

Referring to FIG. 1 and FIG. 14, (A) is a microscope image of a conductive pad 210 in which metal particles MP are applied on a surface thereof according to an embodiment. It can be seen that the metal particles MP are evenly distributed on the conductive pad 210 of an electronic chip CH.

Referring to FIG. 2, FIG. 3, FIG. 4A, and FIGS. 14, (B) and (C) are microscope images showing a cross-section at which a transparent electrode and the electronic chip CH are physically and electrically bonded according to an embodiment. It can be seen that an air gap VO is formed between the metal particles MP.

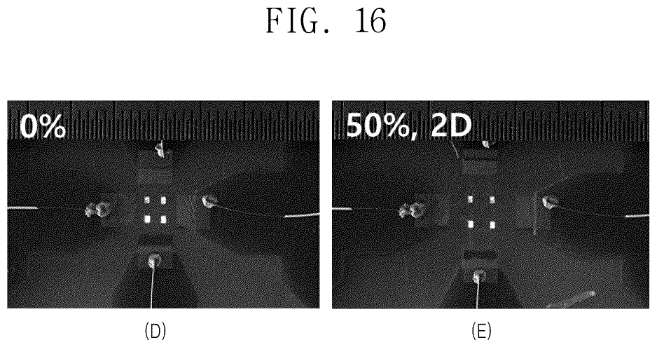

FIG. 15 shows photographs of an experiment of bonding an electronic chip on a substrate according to embodiments of the inventive concept, and then confirming light emission characteristics.

Referring to FIG. 15, as a result of bonding an electronic chip (e.g., an LED chip) onto a transparent substrate and then applying a current thereto according to an embodiment, light emission was confirmed. The transparent substrate may include electrodes. A gap between the electrodes may be, for example, approximately 20 μm. The electronic chip may have, for example, a horizontal width of approximately 600 μm and a vertical width of approximately 300 μm. Thus, it can be seen that light emitting characteristics are maintained by bonding an electronic chip formed with a connection layer to a substrate without forming a bump or a solder ball on the substrate.

FIG. 16 shows photographs of an experiment of bonding an electronic chip on a substrate according to embodiments of the inventive concept, and then performing a tensile test.

Referring to FIG. 16, an electronic chip (e.g., an LED chip) was bonded onto a stretchable substrate and then a current was applied thereto according to an embodiment, and then a tensile test was performed. (D) is a photograph of an initial state before the tensile test was performed. (E) is a photograph after tensioning the substrate up to 50%. The tensile test was performed by applying a force from four directions of upper, lower, left, and right sides of the substrate to tension the substrate. It was confirmed that the electronic chip emitted light normally both before and after tensioning the substrate. It can be seen that the electronic chip and the electronic device according to the inventive concept maintain electrical characteristics even when the substrate is tensioned.

A process of directly forming a bump or a solder ball on a substrate is not performed on an electronic device according to the inventive concept, and instead, a connection layer is formed on an electronic chip. Therefore, it is possible to mass produce the electronic chips including the connection layer, which makes it possible to decrease process time and costs and increase productivity. In addition, it is possible to form the connection layer on the electronic chip regardless of the size of the electronic chips, a wiring pattern, or an interval between conductive pads. Therefore, even if the interval between the connection pads has a fine pitch, the electronic chip may be effectively bonded to the substrate.

The embodiments of the inventive concept have been described with reference to the accompanying drawings. However, the inventive concept may be implemented in other detailed forms without changing the technical spirit or necessary features thereof. Therefore, it is to be understood that the above-described embodiments are exemplary and non-limiting in every aspect.

[Description of the Reference Numerals or Symbols]

| | | | |
|---|---|---|---|
| 100 | Base substrate | 200 | Substrate |
| 210 | Conductive pad unit | 300 | Connection layer |
| AD | Adhesive layer | CH | Electronic chip |
| CR1, CR2, CR3 | Carrier substrate | MP | Metal particles |
| VO | Air gap | | |

What is claimed is:

1. An electronic chip comprising:
a substrate;
conductive pads disposed on a first surface of the substrate; and
a connection layer covering the first surface and the conductive pads,
wherein the connection layer includes an adhesive layer, and metal particles dispersed in the adhesive layer,
wherein the adhesive layer includes tannic acid and polyalcohol.

2. The electronic chip of claim 1, wherein the metal particles comprise at least one of gold (Au), silver (Ag), copper (Cu), tin (Sn), titanium (Ti), tungsten (W), molybdenum (Mo), iron (Fe), zinc (Zn), indium tin oxide (ITO), or an alloy thereof.

3. The electronic chip of claim 1, wherein the metal particles have a spherical shape, a rod shape, or a flake shape.

4. The electronic chip of claim 1, wherein:
each of the conductive pads has a width of approximately 100 nm to approximately 500 nm; and
adjacent conductive pads have a distance of approximately 100 nm to approximately 250 nm therebetween.

5. The electronic chip of claim 1, wherein the metal particles have a particle diameter of approximately 0.1 times to approximately 1 time the width of each of the conductive pads, and approximately 0.1 times to approximately 0.5 times the distance between the conductive pads.

6. The electronic chip of claim 1, wherein the metal particles are connected to the conductive pads.

7. The electronic chip of claim 1, wherein the metal particles dispersed in the adhesive layer have an application area of approximately 40% to approximately 70% of the total area of the conductive pads in a plane view.

8. The electronic chip of claim 1, wherein the polyalcohol comprises at least one of polyvinyl alcohol, polyethylene glycol, or polypropylene glycol.

9. The electronic chip of claim 1, wherein the connection layer has a thickness of approximately 1 μm to approximately 10 μm from the first surface of the substrate.

10. An electronic device comprising:
a base substrate;
electrodes disposed on the base substrate; and
an electronic chip disposed on some corresponding electrodes among the electrodes,
wherein the electronic chip includes:
a substrate;
conductive pads disposed on a first surface of the substrate; and
a connection layer covering the first surface and the conductive pads, interposed between the substrate and the electrodes, and in contact with the electrodes,
wherein the connection layer includes an adhesive layer, and metal particles dispersed in the adhesive layer,
wherein the adhesive layer includes polyphenol and polyalcohol.

11. The electronic device of claim 10, wherein:
the polyphenol comprises at least one of as flavonoid, phenolic acid, stilbene, lignan, or tannic acid; and
the polyalcohol comprises at least one of polyvinyl alcohol, polyethylene glycol, or polypropylene glycol.

12. The electronic device of claim 10, wherein the metal particles comprise at least one of iron (Fe), zinc (Zn), molybdenum (Mo), tungsten (W), or an alloy thereof.

13. The electronic device of claim 10, wherein the metal particles have a particle diameter of approximately 10 nm to approximately 250 nm.

14. The electronic device of claim 10, wherein the connection layer further comprises an air gap between the metal particles.

15. The electronic device of claim 10, wherein the base substrate comprises at least one of a glass substrate, a flexible substrate, a stretchable substrate, or a biodegradable substrate.

16. The electronic device of claim 10, wherein the connection layer is exposed toward the base substrate between the electrodes and has a surface spaced apart from the base substrate.

17. The electronic device of claim 10, wherein:
the connection layer has a maximum width greater than the width of the substrate; and
the connection layer is extended to cover a portion of a side surface of the substrate.

18. An electronic device comprising:
a base substrate;
electrodes disposed on the base substrate; and
an electronic chip disposed on some corresponding electrodes among the electrodes,
wherein the electronic chip includes:
a substrate;
conductive pads disposed on a first surface of the substrate; and
a connection layer covering the first surface and the conductive pads, interposed between the substrate and the electrodes, and in contact with the electrodes,
wherein the connection layer includes an adhesive layer, metal particles dispersed in the adhesive layer, and an air gap between the metal particles,
wherein the adhesive layer includes tannic acid.

19. The electronic device of claim 18, wherein the adhesive layer comprises at least one of polyvinyl alcohol, polyethylene glycol, or polypropylene glycol.

20. The electronic device of claim 18, wherein the conductive pads are connected to the electrodes through the metal particles.
